(19) United States
(12) Patent Application Publication
(10) Pub. No.: US 2024/0284767 A1
(43) Pub. Date: Aug. 22, 2024

(54) DISPLAY PANEL AND MANUFACTURING METHOD THEREOF

(71) Applicants: Chengdu BOE Optoelectronics Technology Co., Ltd., Sichuan (CN); BOE Technology Group Co., Ltd., Beijing (CN)

(72) Inventor: Yunhao WANG, Beijing (CN)

(21) Appl. No.: 18/565,028

(22) PCT Filed: Dec. 21, 2021
(86) PCT No.: PCT/CN2021/140152

§ 371 Date: Nov. 28, 2023

(51) Int. Cl. H10K 59/80; H10K 59/12; H10K 59/40

(52) U.S. Cl. CPC H10K 59/879; H10K 59/1201; H10K 59/40

(57) ABSTRACT

The display panel includes a driving backplane, light-emitting layer, light-condensing layer and light-filtering layer. The light-emitting layer is provided on a side of the driving backplane and includes light-emitting elements. The light-condensing layer is provided on a side of the light-emitting layer away from the driving backplane and has micro-lenses, and one light-emitting element corresponds to at least one micro-lens in a direction perpendicular to the driving backplane. The light-filtering layer covers the light-condensing layer and includes light-filtering parts, one light-filtering part corresponds to one light-emitting element in the direction perpendicular to the driving backplane, and the light-filtering part covers at least one micro-lens. A refractive index of the light-filtering part is greater than that of the light-condensing layer, and the micro-lens can converge at least a portion of light emitted by a corresponding light-emitting element.

### TECHNICAL FIELD

The present disclosure relates to the field of display technology, and in particular, to a display device, a display panel and a method of manufacturing a display panel.

### BACKGROUND

At present, a display panel has become an essential part of an electronic device such as a mobile phone and a TV. Organic electroluminescent display panels have been widely used due to their advantages of wide color gamut, low power consumption and fast response speed. However, the brightness of the organic electroluminescent display panel still needs to be improved.

It is to be noted that the above information disclosed in the Background section is only for enhancement of understanding of the background of the present disclosure and therefore it may contain information that does not form the prior art that is already known to a person skilled in the art.

### SUMMARY

The present disclosure provides a display device, a display panel and a method of manufacturing a display panel.

An aspect of the present disclosure provides a display panel, including:
a driving backplane;
a light-emitting layer, provided on a side of the driving backplane and including a plurality of light-emitting elements;
a light-condensing layer, provided on a side of the light-emitting layer away from the driving backplane and having a plurality of micro-lenses, one of the light-emitting elements being provided to correspond to at least one of the micro-lenses in a direction perpendicular to the driving backplane; and
a light-filtering layer, covering the light-condensing layer and including a plurality of light-filtering parts, one of the light-filtering parts being provided to correspond to one of the light-emitting elements in the direction perpendicular to the driving backplane, and the light-filtering part covering at least one of the micro-lenses,
wherein a refractive index of each of the light-filtering parts is greater than a refractive index of the light-condensing layer, and the micro-lens can converge at least a portion of light emitted by a corresponding light-emitting element.

In an exemplary embodiment of the present disclosure, the display panel further includes:
a touch layer, provided on the side of the light-emitting layer away from the driving backplane; and
a light-absorbing layer, provided on a surface of the touch layer away from the driving backplane,
wherein the light-converging layer covers the light-absorbing layer and the touch layer, and an orthographic projection of the light-absorbing layer on the driving backplane separates orthographic projections of the light-filtering parts on the driving backplane.

In an exemplary embodiment of the present disclosure, the touch layer includes:
a connection layer, including a plurality of connection units;
an isolation layer, covering the connection layer; and
an electrode layer, provided on a surface of the isolation layer away from the driving backplane, and including a plurality of first touch electrodes extending in a row direction and spaced apart in a column direction, and a plurality of electrode unit groups extending in the column direction and distributed in the row direction,
wherein each of the electrode unit groups includes a plurality of electrode units distributed in the column direction, two adjacent electrode units in the same electrode unit group are connected by one of the connection units, and the same electrode unit group and the connection units connected to the same electrode unit group form a second touch electrode, and
wherein the light-absorbing layer covers at least a portion of the electrode layer.

In an exemplary embodiment of the present disclosure, the display panel further includes:
a connection layer, including a plurality of connection units, the light-condensing layer covering the connection layer;
an electrode layer, provided on a surface of the light-condensing layer away from the driving backplane, and including a plurality of first touch electrodes extending in a row direction and spaced apart in a column direction, and a plurality of electrode unit groups extending in the column direction and distributed in the row direction, wherein each of the electrode unit groups includes a plurality of electrode units distributed in the column direction, two adjacent electrode units in the same electrode unit group are connected by one of the connection units, and the same electrode unit group and the connection units connected to the same electrode unit group form a second touch electrode; and
a light-absorbing layer, covering at least a portion of the electrode layer and separating the light-filtering parts.

In an exemplary embodiment of the present disclosure, the display panel further includes:
a connection layer, including a plurality of connection units;
an isolation layer, covering the connection layer; and
an electrode layer, provided on a surface of the isolation layer away from the driving backplane, and including a plurality of first touch electrodes extending in a row direction and spaced apart in a column direction, and a plurality of electrode unit groups extending in the column direction and distributed in the row direction,
wherein each of the electrode unit groups includes a plurality of electrode units distributed in the column direction, two adjacent electrode units in the same electrode unit group are connected by one of the connection units, and the same electrode unit group and the connection units connected to the same electrode unit group form a second touch electrode, and
wherein the light-condensing layer covers the electrode layer, an orthographic projection of the electrode layer on the driving backplane separates orthographic projections of the light-filtering parts on the driving backplane, and the electrode layer is a light-absorbing conductive structure.

In an exemplary embodiment of the present disclosure, the display panel further includes:
a connection layer, including a plurality of connection units, the light-condensing layer covering the connection layer; and
an electrode layer, provided on a surface of the light-condensing layer away from the driving backplane, and including a plurality of first touch electrodes extending in a row direction and spaced apart in a column direction, and a plurality of electrode unit groups extending in the column direction and distributed in the row direction,
wherein each of the electrode unit groups includes a plurality of electrode units distributed in the column direction, two adjacent electrode units in the same electrode unit group are connected by one of the connection units, and the same electrode unit group and the connection units connected to the same electrode unit group form a second touch electrode, and
wherein the electrode layer separates the light-filtering parts, and the electrode layer is a light-absorbing conductive structure.

In an exemplary embodiment of the present disclosure, the electrode layer is a mesh structure having a plurality of mesh holes, each of the mesh holes is surrounded by a plurality of electrode wires, and adjacent mesh holes share at least one of the electrode wires, and
one of the light-filtering parts is provided to correspond to one of the mesh holes in the direction perpendicular to the driving backplane, and a width of the electrode wire is not less than a distance between two adjacent light-filtering parts.

In an exemplary embodiment of the present disclosure, the electrode layer includes a first conductive layer, a second conductive layer and a light-absorbing material layer, and
wherein the second conductive layer covers a surface of the first conductive layer away from the backplane, and at least a portion of the light-absorbing material layer covers a surface of the second conductive layer away from the driving backplane.

In an exemplary embodiment of the present disclosure, the light-absorbing material layer covers sidewalls of the first conductive layer and the second conductive layer.

In an exemplary embodiment of the present disclosure, a material of at least one of the light-absorbing material layer and the first conductive layer is a light-absorbing conductive material.

In an exemplary embodiment of the present disclosure, the light-absorbing conductive material layer includes molybdenum dioxide.

In an exemplary embodiment of the present disclosure, a material of the second conductive layer is aluminium.

In an exemplary embodiment of the present disclosure, the light-filtering part includes a base material and scattering particles dispersed in the base material.

In an exemplary embodiment of the present disclosure, a material of the scattering particle includes zirconia.

In an exemplary embodiment of the present disclosure, the light-emitting layer includes a plurality of light-emitting units distributed in a plurality of arrays, each of the light-emitting units includes at least two light-emitting elements having different light-emitting colors, and a color of any one of the filtering parts is the same as the light-emitting color of a corresponding light-emitting element.

In an exemplary embodiment of the present disclosure, the light-condensing layer has a plurality of the lenses within a range of the light-condensing layer covered by one of the light-filtering parts.

In an exemplary embodiment of the present disclosure, the display panel further includes:
an encapsulation layer, covering the light-emitting layer,
wherein the connection layer is provided on a side of the encapsulation layer away from the driving backplane.

In an exemplary embodiment of the present disclosure, the electrode layer has a thickness of not less than 0.1 μm and not greater than 0.6 μm.

In an exemplary embodiment of the present disclosure, the light-filtering layer has a thickness of not less than 1.0 μm and not greater than 6.0 μm.

In an exemplary embodiment of the present disclosure, the light-absorbing layer has a thickness of not less than 0.5 μm and not greater than 2.0 μm.

In an exemplary embodiment of the present disclosure, the light-condensing layer has a thickness of not less than 0.5 μm and not greater than 5.0 μm.

An aspect of the present disclosure provides a method of manufacturing a display panel, including:
forming a driving backplane;
forming a light-emitting layer including a plurality of light-emitting elements on a side of the driving backplane;
forming a light-condensing layer having a plurality of micro-lenses on a side of the light-emitting layer away from the driving backplane, one of the light-emitting elements being provided to correspond to at least one of the micro-lenses in a direction perpendicular to the driving backplane, and the micro-lens being configured to converge at least a portion of light emitted by a corresponding light-emitting element; and
forming a light-filtering layer covering the light-condensing layer, the light-filtering layer including a plurality of light-filtering parts, one of the light-filtering parts being provided to correspond to one of the light-emitting elements in the direction perpendicular to the driving backplane, and a refractive index the light-filtering layer being greater than a refractive index of the light-condensing layer.

An aspect of the present disclosure provides a display device including any one of the display panels described above.

It should be understood that the above general description and the detailed descriptions that follow are only exemplary and explanatory and do not limit the present disclosure.

### BRIEF DESCRIPTION OF THE DRAWINGS

The accompanying drawings herein are incorporated into and form a part of the specification, illustrate embodiments consistent with the present disclosure, and serve to, in conjunction with the specification, explain the principle of the present disclosure. Obviously, the accompanying drawings in the following description are only some of the embodiments of the present disclosure, and other accompanying drawings may be obtained from these drawings without creative work by those skilled in the art.

FIG. 1 is a schematic diagram of a display panel according to an embodiment of the present disclosure.

FIG. 2 is a schematic diagram of an electrode layer in a display panel according to an embodiment of the present disclosure.

FIG. 3 is a schematic diagram of a light path of a light-exiting structure in a display panel according to an embodiment of the present disclosure.

FIG. 4 is a schematic diagram of a display panel in a first embodiment of the present disclosure.

FIG. 5 is a schematic diagram of a display panel in a second embodiment of the present disclosure.

FIG. 6 is a schematic diagram of a display panel in a third embodiment of the present disclosure.

FIG. 7 is a schematic diagram of a display panel in a fourth embodiment of the present disclosure.

FIG. 8 is a schematic diagram of an electrode layer, a light-filtering part and a micro-lens in the display panel in the first and second embodiments of the present disclosure.

FIG. 9 is a schematic diagram of an electrode layer, a light-filtering part and a micro-lens in the display panel in the third and fourth embodiments of the present disclosure.

### DETAILED DESCRIPTION

Example embodiments will now be described more fully with reference to the accompanying drawings. However, the example embodiments can be implemented in a variety of forms and should not be construed as being limited to the embodiments set forth herein. Rather, these embodiments are provided so that the present disclosure is comprehensive and complete and the concept of the example embodiments is conveyed to those skilled in the art comprehensively. The same reference numerals in accompanying drawings denote the same or similar structures, and thus their detailed descriptions will be omitted. In addition, the accompanying drawings are only schematic illustrations of the present disclosure and are not necessarily drawn to scale.

The terms “a”, “an”, “the”, “said”, and “at least one” are used to indicate the presence of one or more elements/components/etc.; the terms “including” and “having” are used to indicate open-ended inclusion and to mean that there may be additional elements/components/etc. in addition to those listed; and the terms “first”, “second”, “third”, etc., are used only as signs and are not intended to limit the quantity of the objects to which they refer.

The row direction and column direction in the present disclosure refer to two intersecting directions, e.g., the row direction may be the horizontal direction in the accompanying drawings, and the column direction may be vertical direction in the accompanying drawings, which are perpendicular to each other. However, this should not be regarded as a limitation of the row direction and the column direction, the row direction does not necessarily refer to the horizontal direction and the column direction does not necessarily refer to the vertical direction. Those skilled in the art may know that the actual orientations of the row direction and the column direction may be changed if the display panel has a position change such as rotation.

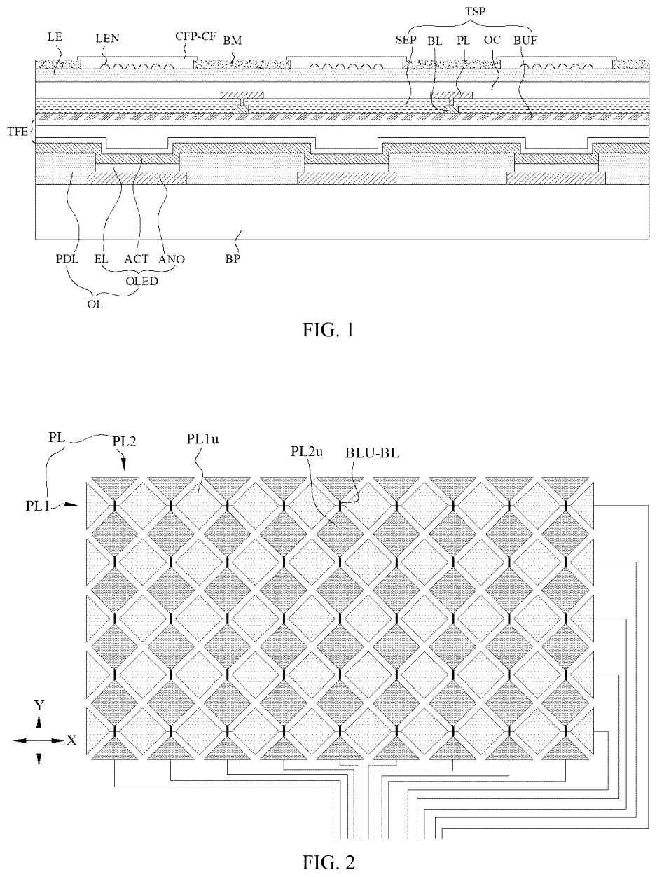

An embodiment of the present disclosure provides a display panel, as shown in FIGS. 1 to 3, which may include a driving backplane BP, a light-emitting layer OL, a light-condensing layer LE, and a light-filtering layer CF.

The light-emitting layer OL is provided on a side of the driving backplane BP and includes a plurality of light-emitting elements LED.

The light-condensing layer LE is provided on a side of the light-emitting layer OL away from the driving backplane BP and has a plurality of micro-lenses LEN, and one of the light-emitting elements LED is provided to correspond to at least one of the micro-lenses LENs in a direction perpendicular to the driving backplane BP.

The light-filtering layer CF covers the light-condensing layer LE and includes a plurality of light-filtering parts CFP, one of the light-filtering parts CFP is provided to correspond to one of the light-emitting elements LED in the direction perpendicular to the driving backplane BP, and the light-filtering part CFP covers at least one micro-lens (LEN).

A refractive index of each of the light-filtering parts CFP is greater than a refractive index of the light-condensing layer LE, and the micro-lens LEN can converge at least a portion of light emitted by a corresponding light-emitting element LED.

In the display panel according to an embodiment of the present disclosure, the light emitted from the light-emitting element LED is refracted when entering the light-filtering part CFP from the micro-lens LEN corresponding to the light-emitting element LED. Since the refractive index of the light-filtering part CFP is greater than that of the light-condensing layer LE, the light that enters the light-filtering part CFP from the micro-lens LEN can be converged, so that the light emitted from the light-emitting element LED is concentrated to achieve a light-condensing effect, and thus the brightness of the display panel is increased. At the same time, the light-filtering part CFP can pass only light of the same color as the color thereof, so that the light that enters the display panel from the outside can be reduced, thereby reducing the reflection of outside light by the inside of the display panel, and improving the display effect. In addition, since the light-filtering part CFP can reduce the light reflection, it can avoid a case where a circular polarizer with a relatively large thickness is used to reduce the light reflection, therefore the thickness of the film layer provided on a side of the light-emitting element LED away from the driving backplane BP can reduced, which is conducive to weakening the restriction of the light-emitting range of the light-emitting element LED by the film layer, and thus avoiding the narrowing of the light-emitting range due to the light condensing effect of the micro-lens LEN. As a result, the brightness can be increased without reducing the light-emitting range.

Each part of the display panel is described in detail below:

As shown in FIG. 1, the driving backplane BP has a driving circuit for driving the light-emitting layer OL to emit light. The driving backplane BP may include a substrate and a driving layer.

As shown in FIG. 1, the substrate may be a flat plate as a carrier, and may have a rectangular or other shape. The material of the substrate may include a transparent rigid material such as glass or a flexible material such as polyimide (PI). The substrate may be a single-layer or multi-layer structure, which is not specifically limited herein.

The driving layer may be directly stacked on a side of the substrate. Alternatively, in order to avoid impurities in the substrate from affecting the driving layer, a buffer layer BUF may be provided between the substrate and the driving layer, and the driving layer may be provided on a surface of the buffer layer BUF away from the substrate. The driving layer includes at least a driving area and a peripheral area, and the peripheral area may be an encircling area surrounding the driving area. Alternatively, the peripheral area may be two discontinuous areas separated at two sides of the driving area, as long as it is located outside of the driving area.

The driving layer has a driving circuit for driving the light-emitting element LED to emit light, the driving circuit may include a plurality of pixel circuits and a peripheral circuit, the pixel circuit is provided within the driving area. Of course, portions of some of the pixel circuits may be located in the peripheral area. The number of pixel circuits may be the same as the number of light-emitting elements LED, and the pixel circuits are respectively connected to the light-emitting elements LED in one-to-one correspondence so as to control respective light-emitting elements LED to emit light independently. Of course, the same pixel circuit may also be connected to a plurality of light-emitting elements LED so as to drive the plurality of light-emitting elements LED to emit light. The peripheral circuit is located in the peripheral area, and the peripheral circuit is connected to the pixel circuit to input a driving signal to the pixel circuit for controlling the light-emitting element LED to emit light. The peripheral circuit may include a light-emitting control circuit, a gate driving circuit and a source driving circuit, and a power supply circuit.

The pixel circuit may have a structure such as 7T1C, 7T2C, 6T1C or 6T2C, which is not specifically limited herein as long as it can drive the light-emitting element LED to emit light. The nTmC indicates that a pixel circuit includes n transistors (denoted by the letter “T”) and m capacitors (denoted by the letter “C”). Of course, one pixel circuit may also be connected to a plurality of light-emitting elements LED at the same time, and the plurality of light-emitting elements LED may be driven to emit light at the same time or in a time-sharing manner.

The thin-film transistor of the above-described driving layer may be a top-gate or bottom-gate type thin-film transistor, and each thin-film transistor may include an active layer, a gate electrode, a source electrode, and a drain electrode. The gate electrode may be a double-gate structure or may be a single-gate or other structure. For respective thin-film transistors, the active layers are provided in the same layer, the gate electrodes are provided in the same layer, and the source electrodes and the drain electrodes are provided in the same layer, in order to simplify the process.

The structure of the driving layer will be illustrated exemplarily by taking a top-gate type thin film transistor as an example.

The driving layer may include an active layer, a first gate insulating layer, a gate electrode, a second gate insulating layer, an interlayer dielectric layer, a source-drain layer, and a planarization layer.

The active layer is provided on a side of the substrate, and the first gate insulating layer covers the active layer. The gate electrode is provided on a surface of the first gate insulating layer away from the substrate to correspond to the active layer. The second gate insulating layer covers the gate electrode and the first gate insulating layer. The interlayer dielectric layer covers the second gate insulating layer. The source-drain layer is provided on a surface of the interlayer dielectric layer away from the substrate, and includes a source electrode and a drain electrode. The source electrode and the drain electrode are connected to the two ends of the active layer through contact holes. The planarization layer covers the source-drain layer and the interlayer dielectric layer. Of course, the driving layer may also include other film layers, as long as it can drive the light-emitting element LED to emit light, which will not be described in detail here.

As shown in FIG. 1, the light-emitting layer OL may be provided on a side of the driving backplane BP, for example, the light-emitting layer OL is provided on a surface of the planarization layer away from the substrate. The light-emitting layer OL may include a plurality of light-emitting elements LED arranged in an array, and each of the light-emitting elements LED may emit light when being driven by the pixel circuit.

In some embodiments of the present disclosure, the light-emitting element LED is an organic light-emitting diode (OLED), which may include a first electrode ANO, a light-emitting function layer EL, and a second electrode CAT stacked sequentially in the direction away from substrate.

The first electrode ANO may be provided on a surface of the planarization layer away from the substrate and is connected to the pixel circuit through a contact hole. The first electrode ANO may be a single-layer or a multi-layer structure, which may serve as an anode of the light-emitting element LED.

As shown in FIG. 1, the light-emitting function layer EL is provided on a surface of the first electrode ANO away from the substrate, and may include a hole-injecting layer, a hole-transporting layer, a composite light-emitting layer OL, an electron-transporting layer, and an electron-injecting layer stacked sequentially in a direction away from the substrate, and furthermore, an electron-blocking layer may be provided between the hole-transporting layer and the composite light-emitting layer OL.

As shown in FIG. 1, the second electrode CAT covers the light-emitting function layer EL and may extend to the peripheral area. The second electrode CAT may be connected to a power supply signal terminal so as to receive a second power supply signal VSS. The first electrode ANO and the second electrode CAT may act together to cause the light-emitting element LED to emit light, and the specific light-emitting principle of the organic light-emitting diode will not be described in detail herein. The material of the second electrode CAT may be magnesium (Mg), silver alloy, or other materials.

Of course, in other embodiments of the present disclosure, the light-emitting element LED may also employ a Quantum Dot Light Emitting Diode (QLED), which may include a first electrode, a quantum dot light-emitting layer, and a second electrode stacked in a direction away from the driving backplane BP. The quantum dot light-emitting layer may be made of an inorganic material, which may include a hole-transporting layer, a quantum dot layer, and an electron-transporting layer stacked in the direction away from the driving backplane BP. Holes provided by the first electrode and electrons provided by the second electrode may be combined in the quantum dot layer to form excitons, thereby emitting light, and the specific principle of the quantum dot light-emitting diode will not be described in detail herein.

As shown in FIG. 1, in order to define the range of each light-emitting element LED, the light-emitting layer OL may also include a pixel-defining layer PDL, which may be provided on a surface of the first electrode ANO away from the driving backplane, and is provided with a plurality of openings to expose the first electrodes ANO respectively in one-to-one correspondence. The shape of the opening may be a polygon such as quadrangle, pentagon and hexagon, and may also be a circle, oval, and other shapes, which is not specifically limited herein. The light-emitting function layer EL is stacked on an area of the first electrode ANO located within the opening. The light-emitting function layers EL of the light-emitting elements LED are arranged independently and spaced apart from each other. Different light-emitting function layers have different light-emitting colors. The second electrode CAT covers each of the light-emitting function layers EL at the same time, so that each of the light-emitting elements LED can share the same second electrode CAT. Each of the light-emitting elements LED may be defined by the above-described plurality of openings, and the boundary of any one of the light-emitting elements LED is the boundary of the corresponding opening thereto.

The light-emitting elements LED include a plurality of light-emitting elements LED with different light-emitting colors, for example, a first light-emitting element LED that emits red light, a second light-emitting element LED that emits green light, and a third light-emitting element that emits blue light. The light-emitting layer OL may be divided into a plurality of light-emitting units arranged in an array, and each light-emitting unit includes at least two light-emitting elements LED with different light-emitting colors. For example, one light-emitting unit may include one first light-emitting element, one second light-emitting element, and one third light-emitting element. The color of any of the light-filtering parts CFP is the same as the light-emitting color of the light-emitting element LED corresponding thereto.

As shown in FIG. 1, in some embodiments of the present disclosure, the display panel may further include an encapsulation layer TFE, which may cover the surface of the light-emitting layer OL away from the driving backplane BP and cover all of the light-emitting elements LED, so as to protect the light-emitting layer OL from being corroded by external water and oxygen. At the same time, the boundary of the encapsulation layer TFE extends to the peripheral area, but not beyond the peripheral area, and can also protect the peripheral circuitry in the peripheral area.

For example, a thin-film encapsulation (TFE) may be used to achieve encapsulation. The encapsulation layer TFE may include a first inorganic layer, an organic layer, and a second inorganic layer. The first inorganic layer covers a surface of the light-emitting layer OL away from the driving backplane BP. The organic layer may be provided on a surface of the first inorganic layer away from the driving backplane BP, and the boundary of the organic layer is limited inside the boundary of the first inorganic layer. The second inorganic layer covers the organic layer and a portion of the first inorganic layer not covered by the organic layer. The second inorganic layer may block water and oxygen, and the organic layer having flexibility may achieve planarization.

As shown in FIG. 1, the display panel may further include a touch layer TSP, which may be provided on a side of the encapsulation layer TFE away from the driving backplane BP. The touch layer TSP may adopt a self-capacitive or mutual-compatible touch structure. For example, the touch layer TSP may be external, or may also be of an On-CELL type such as Flexible Multi-Layer On CELL (FMLOC). The special structure thereof is not specifically limited herein, as long as the touch function can be achieved.

As shown in FIGS. 1 and 2, by taking the touch layer TSP with a mutual-compatible structure as an example, the touch layer TSP may include a connection layer BL, an isolation layer SEP, and an electrode layer PL.

The connection layer BL may be provided on a side of the encapsulation layer TFE away from the driving backplane BP, and includes a plurality of connection units BLU. The material of the connection layer BL is a metal or other conductive material. The connection layer BL may include a plurality of connection unit BLU groups distributed along a row direction, and each group includes a plurality of connection units BLUs arranged and spaced apart along a column direction.

The isolation layer SEP may cover the connection layer BL. The material of the isolation layer SEP is a transparent insulating material. The isolation layer SEP is provided with a plurality of contact holes, each of which exposes a portion of one of the connection units BLU. The same connection unit BLU is exposed by at least two of the contact holes distributed along the column direction.

As shown in FIG. 2, the electrode layer PL may be provided on a surface of the isolation layer SEP away from the driving backplane BP, and includes a plurality of first touch electrodes PL1 and a plurality of second touch electrodes PL2.

The first touch electrodes PL1 extend along a row direction X and are spaced apart along a column direction Y. The first touch electrode PL1 may include a plurality of electrode units PL1u distributed along the row direction X, two adjacent electrode units PL1u may be connected by the connection unit, and the electrode unit PL1u may have a rhombus or other polygonal shape.

The second touch electrodes PL2 may extend along the column direction Y and are distributed along the row direction X such that each first touch electrode PL1 crosses the second touch electrode PL2. In order to prevent the first touch electrode PL1 and the second touch electrode PL2 from short-circuiting at the intersection, one second touch electrode PL2 may include an electrode unit group. The electrode unit group may include a plurality of electrode units PL2u distributed and spaced apart along the column direction Y. The shape of the electrode unit PL2u may be the same as the shape of the electrode unit PL1u of the first touch electrode PL1. Two adjacent electrode units PL2u in the same electrode unit group are connected to the connection unit BLU through at least two contact holes, such that the same electrode unit group and the connection unit BLU connected thereto may form the second touch electrode PL2. Orthographic projections, on the driving backplane BP, of the connection unit of the first touch electrode PL1 and the connection unit BLU of the second touch electrode PL2 are intersected, and the electrode unit PL1u of the first touch electrode PL1 and the electrode unit PL2u of the second touch electrode PL2 which are adjacent to each other have a gap GAP therebetween so that a capacitor may be formed.

One of the first touch electrode PL1 and the second touch electrode PL2 may be used as a sensing electrode and the other one thereof may be used as a driving electrode. At the time of touching, a driving signal may be applied to the driving electrode and a sensing signal may be detected by the sensing electrode. By processing the sensing signal and the driving signal, a capacitance change between the first touch electrode PL1 and the touch electrode may be determined, and thus the touching position may be determined.

In some embodiments of the present disclosure, the electrode layer PL may be a mesh structure having a plurality of mesh holes, and the mesh hole is a through-hole. Each mesh hole is surrounded by a plurality of electrode wires LP, and may be of a polygonal structure such as quadrangle, pentagon and hexagon, or may also of a circle, oval or the like. Adjacent mesh holes share at least one of the electrode wires LP. Each of the first touch electrode PL1 and the second touch electrode PL2 is a portion of the mesh structure. The gap GAP between adjacent electrode units PL1u and PL2u may be formed by cutting away a portion of the electrode wire LP.

In order to reduce the blocking of the light-emitting element LED by the touch layer TSP, the mesh hole of the electrode layer PL may be provided in correspondence with the light-emitting element LED. Each light-emitting element LED corresponds to one mesh hole through which light emitted from the light-emitting element LED may pass. Of course, one light-emitting element LED may also correspond to a plurality of mesh holes, or one mesh hole may also correspond to a plurality of light-emitting elements LED.

Further, as shown in FIG. 1, the touch layer TSP may also include a buffer layer BUF and a protective layer OC, which may cover the encapsulation layer TFE. The connection layer BL may be provided on a surface of the buffer layer BUF away from the driving backplane BP. The material of the buffer layer BUF may include an insulating material such as silicon nitride and silicon oxide, to avoid impurities of the encapsulation layer TFE from affecting the connection layer BL. The protective layer OC may cover the electrode layer PL to protect the electrode layer PL, and the material of the protective layer OC may be an optical adhesive or other insulating material.

As shown in FIG. 1, in the display panel of the present disclosure, a light-exiting structure may be provided to improve the brightness of the display panel, and at the same time, to reduce the reflecting effect of outside light by the inside of the display panel. The light-exiting structure may include the light-condensing layer LE and the light-filtering layer CF, the light-condensing layer LE has the micro-lens LEN, the light-filtering layer CF covers the light-condensing layer LE, and the refractive index of the light-filtering layer CF is greater than the refractive index of the light-condensing layer LE. According to the law of refraction, the light converges with respect to the incidence direction when passing through the micro-lens LEN and then entering the light-filtering layer CF, i.e., concentrates, so that the light that finally exits condenses, resulting in an increase in luminance. As shown in FIG. 1, it is specified as follows.

The light-condensing layer LE may be provided on a side of the light-emitting layer OL away from the driving backplane BP, for example, the light-condensing layer LE may be provided on a side of the encapsulation layer away from the driving backplane BP. The light-condensing layer LE may have a plurality of micro-lenses LEN, and the micro-lens LEN may be a protrusion structure formed by the surface of the light-condensing layer LE away from the driving backplane BP protruding towards a direction away from the driving backplane BP. The protrusion structure may be a hemispherical structure or a spherical cap structure, of course, it may also be a frustum or other structure, the shape of which is not specifically limited herein.

One light-emitting element LED may be provided in correspondence with at least one micro-lens LEN in a direction perpendicular to the driving backplane BP, i.e., the orthographic projection of one light-emitting element LED on the driving backplane BP at least partially coincides with the orthographic projection of at least one micro-lens LEN on the driving backplane BP.

In some embodiments of the present disclosure, the light-condensing layer LE may have a plurality of lens zones distributed in an array, and each lens zone is provided with a plurality of micro-lenses LEN. The orthographic projection of any of the light-emitting elements LED on the light-condensing layer LE may cover one lens zone, i.e., one light-emitting element LED may correspond to a plurality of micro-lenses LEN. The number of micro-lenses LEN corresponding to each light-emitting element LED may match the size of the light-emitting element LED, and the larger the light-emitting element LED, the greater the number of micro-lenses LEN corresponding to the light-emitting element LED. The size of the light-emitting element LED is the size of the area of the orthographic projection, on the driving backplane BP, of the opening of the pixel-defining layer defining the light-emitting element LED.

The material of the light-condensing layer LE may be a lens material such as resin and acrylic, which is not specifically limited herein.

The light-filtering layer CF may cover the light-condensing layer LE, i.e., the light-filtering layer CF covers a surface of the light-condensing layer LE away from the driving backplane BP, i.e., the light-filtering layer CF is in direct contact with the light-condensing layer LE. The light-filtering layer CF may include a plurality of light-filtering parts CFP, one of the light-filtering parts CFP is provided to correspond to one of the light-emitting elements LED in the direction perpendicular to the driving backplane BP, i.e., the orthographic projection of one light-filtering part CFP on the light-emitting layer OL covers one light-emitting element LED, and an area of the orthographic projection of the light-filtering part CFP on the light-emitting layer OL is not smaller than the area of the light-emitting element LED corresponding thereto. Each of the light-filtering parts CFP can pass through light of one color only, and the color of any one of the light-filtering parts CFP is the same as the light-emitting color of the light-emitting element LED corresponding thereto, so that it can pass through only light emitted by the light-emitting element LED corresponding thereto. Each light-filtering part CFP may cover at least one lens, e.g., each light-filtering part CFP may cover the respective micro-lens LEN within one lens zone.

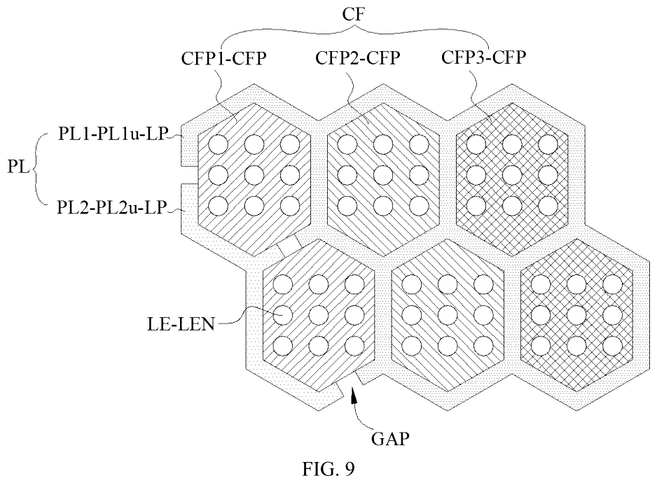

As shown in FIGS. 8 and 9, the light-filtering part CFP corresponding to the first light-emitting element is a first light-filtering part CFP1, the light-filtering part CFP corresponding to the second light-emitting element is a second light-filtering part CFP2, and the light-filtering part CFP corresponding to the third light-emitting element is a third light-filtering part CFP3.

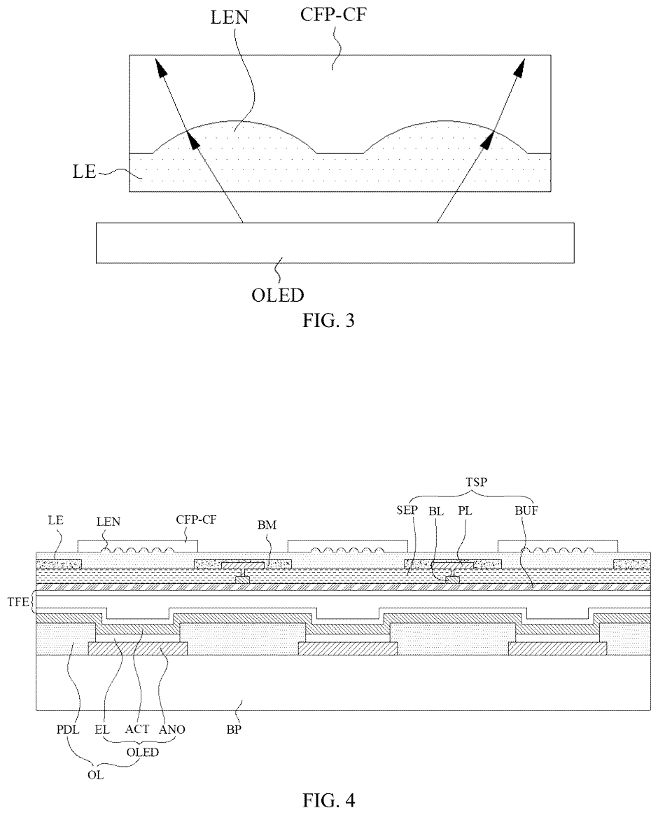

As shown in FIG. 3, the refractive index of each light-filtering part CFP is greater than the refractive index of the light-condensing layer LE, so that when the light is incident on the light-filtering part CFP from the micro-lens LEN, the light will be refracted, and according to the law of refraction, the propagation direction of the exiting light converges to the optical axis of the micro-lens LEN in comparison with the incident light, i.e., concentrates, so that the light can be condensed in a way that reduces the light-emitting range, and thus the brightness of the display panel can be improved. At the same time, since the light-filtering part CFP can pass only monochromatic light and filter out light of other colors, most of the light from the outside can be blocked, thereby reducing the influence, on the display effect, of the reflection of the light from the outside by the second electrode ACT and the first electrode ANO of the light-emitting element LED and the pixel circuit of the driving backplane BP. Further, even though light from the outside enters into the display panel through the light-filtering part CFP and is reflected by the second electrode ACT, the first electrode ANO or the like, at least a portion of the reflected light, when arriving at a different light-filtering part CFP from that the light enters from the outside, cannot exit, which can also reduce light reflection.

In order to ensure that the micro-lens LEN converges the light, the center of curvature of the micro-lens LEN may be located at a side, close to the driving backplane BP, of the light-emitting surface of the light-emitting element LED. For example, if the micro-lens LEN is a hemispherical structure or a spherical cap structure, the center of curvature thereof is the center of the circle thereof; and if the micro-lens LEN is a frustum structure, the center of curvature thereof may be the center of the incircle or excircle thereof.

In some embodiments of the present disclosure, the light-filtering part CFP may include a base material and scattering particles dispersed within the base material, the base material may be a resin or other organic material, and the material of the scattering particle may be a metal oxide, which may be zirconia. Through the scattering effect of the scattering particle on the light, the refractive index of the light-filtering part CFP is larger than that of the light-condensing layer LE.

In other embodiments of the present disclosure, both the base material and the scattering particle may be made of other materials, or, the scattering particles may be made of a plurality of different materials. Of course, other materials with a refractive index greater than that of the light-condensing layer LE may also be employed.

In some embodiments of the present disclosure, as shown in FIG. 1, the display panel may further include a light-absorbing layer BM, which may be disposed in the same layer as the light-filtering part CFP. The light-absorbing layer BM may separate the light-filtering parts CFPs and may absorb light. The light-absorbing layer BM may include a material such as black resin, metal, or metal oxide. The light-absorbing layer BM may block the gap between the light-filtering parts CFPs, thereby preventing the light from exiting the gap and further reducing the reflection of light from the outside, and at the same time, avoiding the overlapping of light emitted from adjacent light-emitting elements LEDs with different colors, which can lead to color deviation.

In the display panel of the present disclosure, a portion of the film layers may be omitted, and the light-condensing layer LE and the light-filtering layer CF may be used to play the role of the omitted film layer, thereby reducing the overall thickness of the display panel, which is conducive to reducing the loss of light, and increasing the range of light emission. At the same time, it can also reduce the distance between the light-absorbing layer BM and the light-emitting layer OL, thereby reducing the restriction of the light-absorbing layer BM on the light-emitting range of the light-emitting element LED, and thus increasing the light-emitting range. In order to reduce the distance between the light-absorbing layer BM and the light-emitting layer OL, it may directly change the position of the light-absorbing layer BM, or it may omit the light-absorbing layer BM and use an other film layer closer to the light-emitting layer OL to play the role of the light-absorbing layer BM. The display panel of the present disclosure will be illustrated below in a plurality of embodiments.

### First Embodiment

As shown in FIGS. 4 and 8, the light-absorbing layer BM may be provided on a surface of the touch layer TSP away from the driving backplane BP, e.g., orthographic projections of a first light-filtering part CFP1, a second light-filtering part CFP2, a third light-filtering part CFP3 on the touch layer TSP are respectively located within three different mesh holes of the electrode layer PL, and the width of the electrode wire LP is smaller than the gap between the two light-filtering parts CFPs, such that each of the light-filtering parts CFP is smaller than the mesh hole. At the same time, each light-filtering part CFP1 corresponds to a plurality of micro-lenses LEN.

The light-absorbing layer BM may be provided on a surface of the isolation layer SEP away from the driving backplane BP, and the light-absorbing layer BM may cover at least a portion of the electrode layer PL. The light-absorbing layer BM is not provided in the gap between the light-filtering parts CFP, thereby reducing the distance between the light-absorbing layer BM and the light-emitting element LED. At the same time, an orthographic projection of the light-absorbing layer BM on the driving backplane BP separates orthographic projections of respective light-filtering parts CFP on the driving backplane BP, thereby ensuring a shading effect of the light-absorbing layer BM on the gap between the light-filtering parts CFP. In addition, the light-condensing layer LE may cover the light-absorbing layer BM and the touch layer TSP, i.e., the light-condensing layer LE covers the light-absorbing layer BM and the electrode layer PL, which may play the role of the protective layer OC, so that the protective layer OC of the touch layer TSP may be omitted, thereby reducing the thickness of the display panel, which is conducive to simplifying the process.

### Second Embodiment

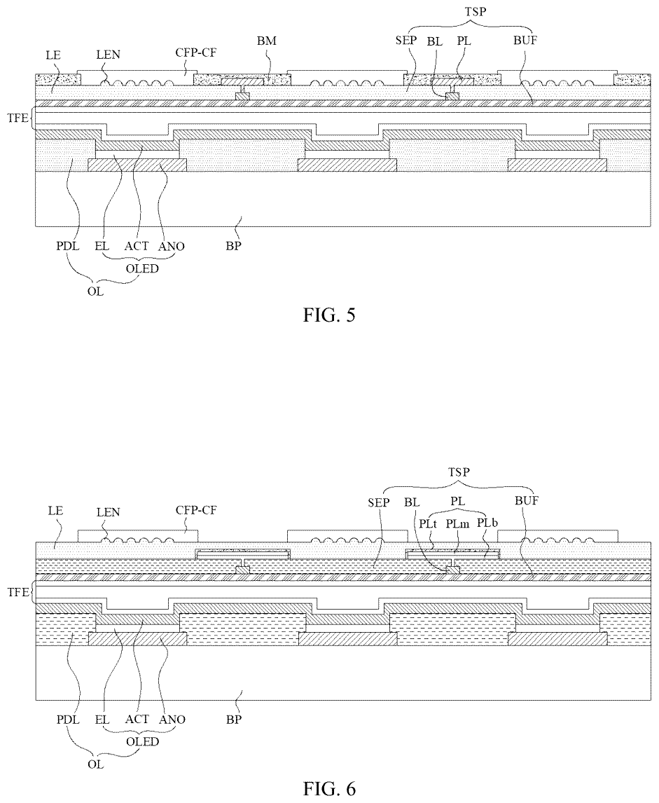

As shown in FIGS. 5 and 8, the connection layer BL may be covered by the light-condensing layer LE, the electrode layer PL may be provided on a surface of the light-condensing layer LE away from the driving backplane BP, the light-filtering layer CF may be provided on a surface of the light-condensing layer LE away from the driving backplane BP, and the light-absorbing layer BM may cover at least a portion of the electrode layer PL, and separate respective light-filtering parts CFP. For example, orthographic projections of the first light-filtering part CFP1, the second light-filtering part CFP2, the third light-filtering part CFP3 on the touch layer TSP are respectively located within three different mesh holes of the electrode layer PL, and the width of the electrode wire LP is smaller than the gap between the two light-filtering parts CFPs, such that each of the light-filtering parts CFP is smaller than the mesh hole. At the same time, each light-filtering part CFP1 corresponds to a plurality of micro-lenses LEN.

The light-condensing layer LE may be used to replace the isolation layer SEP of the touch layer TSP, and the light-filtering layer CF may be used to replace the protective layer OC of the touch layer TSP, so that the isolation layer SEP and the protective layer OC may be omitted, and the thickness of the display panel can be reduced. Although the light-absorbing layer BM is provided in the same layer as the light-filtering layer CF, since the overall thickness is reduced so that the distance between the light-absorbing layer BM and the light-emitting layer OL can be decreased, the light-emitting range can be increased as well.

### Third Embodiment

As shown in FIG. 6, the light-condensing layer LE may be provided on the surface of the isolation layer SEP away from the driving backplane BP, and covers the electrode layer PL. The light-absorbing layer LE may be used to replace the protective layer OC of the touch layer TSP, and at the same time, the electrode layer PL may use a light-absorbing conductive structure, and have an orthographic projection on the driving backplane BP that separates from the orthographic projections of the respective light-filtering parts CFP on the driving backplane BP, so that the electrode layer PL may play the role of the light-absorbing layer BM, and thus the light-absorbing layer BM may be omitted in order to simplify the structure and process. At the same time, the electrode layer PL is closer to the light-emitting layer OL, which is conducive to increasing the light-emitting range.

As shown in FIG. 9, by way of example, orthographic projections of the first light-filtering part CFP1, the second light-filtering part CFP2, and the third light-filtering part CFP3 on the touch layer TSP coincide with three different mesh holes of the electrode layer PL in one-to-one correspondence, and the area of the light-filtering part CFP is not smaller than that of a corresponding mesh hole, i.e., the width of the electrode wire LP is not smaller than the gap between the two light-filtering parts CFPs, so that the electrode wire LP may be used to replace the light-absorbing layer BM. At the same time, each light-filtering part CFP1 corresponds to a plurality of micro-lenses LEN.

### Fourth Embodiment

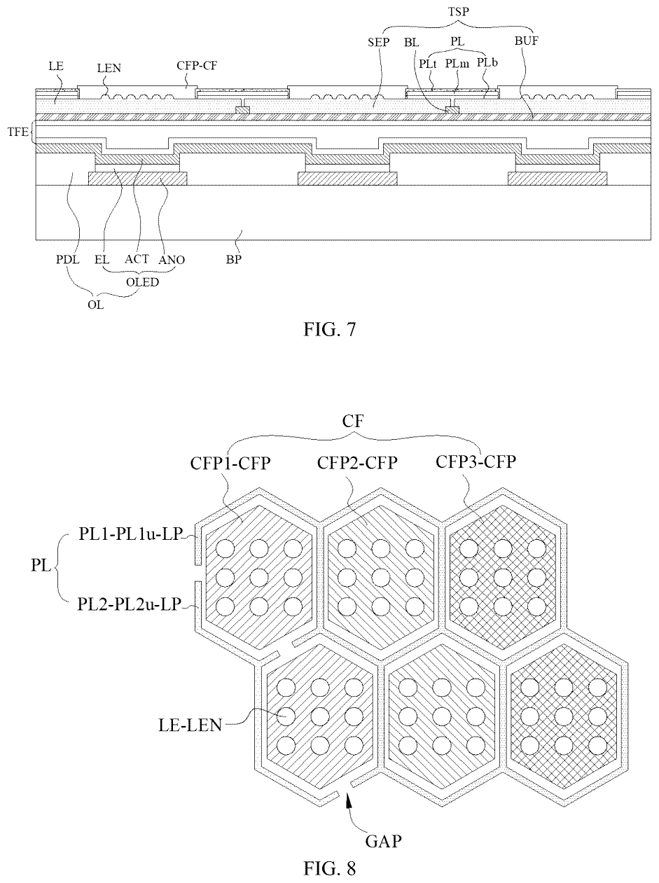

As shown in FIG. 7, the connection layer BL may be covered by the light-condensing layer LE, the electrode layer PL may be provided on a surface of the light-condensing layer LE away from the driving backplane BP, and the light-filtering layer CF and the electrode layer PL may be provided on a surface of the light-condensing layer LE away from the driving backplane BP. The light-condensing layer LE may be used to replace the isolation layer SEP of the touch layer TSP, and the light-filtering layer CF may be used to replace the protective layer OC of the touch layer TSP, so that the isolation layer SEP and the protective layer OC may be omitted, and thus the thickness of the display panel can be reduced. At the same time, the electrode layer PL may separate respective light-filtering parts CFP, i.e., the electrode layer PL is disposed on the gap between the light-filtering parts CFP, and the electrode layer PL is a light-absorbing conductive structure, therefore the light-absorbing layer BM may be replaced by the electrode layer PL, and the light-absorbing layer BM is omitted in order to simplify the structure and process.

As shown in FIG. 9, by way of example, orthographic projections of the first light-filtering part CFP1, the second light-filtering part CFP2, and the third light-filtering part CFP3 on the touch layer TSP coincide with three different mesh holes of the electrode layer PL in one-to-one correspondence, and the area of the light-filtering part CFP is not smaller than that of a corresponding mesh hole, i.e., the width of the electrode wire LP is not smaller than the gap between the two light-filtering parts CFPs, so that the electrode wire LP may be used to replace the light-absorbing layer BM. At the same time, each light-filtering part CFP1 corresponds to a plurality of micro-lenses LEN.

It is to be noted that FIGS. 8 and 9 are only exemplary illustrations of the distribution manner and size relationship of the light-filtering part CFP, the electrode layer PL and the micro-lens LEN, and do not constitute a specific limitation of the structure, number, size and other information thereof, and that the shapes of the light-filtering part CFP and the electrode layer PL may be other shapes, and may be the same or different, and that the sizes of different light-filtering parts CFP may be different as long as the size of the corresponding light-emitting element LED thereto matches the size of the light-filtering part CFP. There may be more or less micro-lenses LEN corresponding to each light-filtering part and mesh hole, and they may be distributed in other ways, which is not limited by the manner illustrated in the drawings.

The following is a detailed description for the electrode layer PL of the light-absorbing structure in the third and fourth embodiments.

As shown in FIGS. 6 and 7, the electrode layer PL may have a multilayer structure and at least some of the film layers thereof are of light-absorbing materials, or one or more layers of the electrode layer PL may be directly made of light-absorbing conductive materials, which is exemplified as follows.

The electrode layer PL may include a first conductive layer PLb, a second conductive layer PLm and a light-absorbing material layer PLt.

The second conductive layer PLm covers a surface of the first conductive layer PLb away from the driving backplane BP, and at least a portion of the light-absorbing material layer PLt covers a surface of the second conductive layer PLm away from the driving backplane BP. That is, the first conductive layer PLb, the second conductive layer PLm, and at least a portion of the light-absorbing material layer PLt are sequentially stacked in the direction away from the driving backplane BP.

The first conductive layer PLb and the light-absorbing material layer PLt may serve to protect the second conductive layer PLm, and the light-absorbing material layer PLt may serve to absorb light. The materials of the first conductive layer PLb and the second conductive layer PLm are both metals or other conductive materials for transmitting signals, and the resistivity of the second conductive layer PLm is less than that of the first conductive layer PLb and the light-absorbing material layer PLt. The light-absorbing material layer PLt may be of light-absorbing material so as to absorb light and play the role of the light-absorbing layer BM.

Of course, in order to improve the light-absorbing effect, the light-absorbing material layer PLt may extend along the sidewalls of the first conductive layer PLb and the second conductive layer PLm in a direction towards the driving backplane BP so as to cover the sidewalls of the first conductive layer and of the second conductive layer, that is to say, the first conductive layer PLb and the second conductive layer PLm may be encapsulated by the light-absorbing material layer PLt.

Further, the material of at least one of the light-absorbing material layer PLt and the first conductive layer PLb is a light-absorbing conductive material. For example, both the light-absorbing material layer PLt and the first conductive layer PLb may be made of a light-absorbing conductive material, which may decrease the resistance thereof while absorbing light. Of course, the material of the light-absorbing material layer PLt may also be a light-absorbing insulating material.

The light-absorbing conductive material described above may include molybdenum dioxide or other black metals or metal oxides, as long as it can conduct electricity and absorb light. The material of the second conductive layer PLm may be a metal with low resistivity such as aluminium or silver, and the material of the first conductive layer PLb may be a metal with a stable chemical property such as titanium. The following table shows a comparison of the reflectivity of molybdenum dioxide and black resin of different thicknesses:

| Material and thickness | Black resin | Molybdenum | Molybdenum | Molybdenum |
|---|---|---|---|---|
| thereof | 2.0 μm | dioxide 15 nm | dioxide 35 nm | dioxide 55 nm |
| Reflectivity @550 | 4.1% | 59.7% | 16.9% | 4.2% |

It can be seen that as the thickness increases, the reflectivity of the molybdenum dioxide gradually decreases and the light-absorbing effect is enhanced, and the thickness of the molybdenum dioxide is smaller than that of the black resin, so that the molybdenum dioxide with a smaller thickness can play the role of the black resin, which is conducive to reducing the thickness of the display panel.

In some embodiments of the present disclosure, the light-absorbing material layer PLt and the first conductive layer PLb may be made of the same material, e.g., molybdenum dioxide, and the second conductive layer PLm is made of aluminium. Alternatively, the material of the light-absorbing material layer PLt is molybdenum dioxide, the material of the first conductive layer PLb is titanium, and the material of the second conductive layer PLm is aluminium.

Further, in some embodiments of the present disclosure, one light-filtering part CFP is provided to correspond to one mesh hole of the electrode layer PL in a direction perpendicular to the driving backplane BP, so that the electrode wire LP enclosing the mesh hole corresponds to the gap between two adjacent light-filtering parts CFP, and the electrode wire LP can be used to replace the light-absorbing layer BM. At the same time, in order to ensure the light absorbing effect, the width of the electrode wire LP may be not less than a distance between two adjacent light-filtering parts CFP.

The thickness and other dimensions of some of the film layers are illustrated exemplarily below.

For the above-described first to fourth embodiments, the thickness of the electrode layer PL is not less than 0.1 μm and not more than 0.6 μm, for example, 0.1 μm, 0.2 μm, 0.3 μm, 0.4 μm, 0.5 μm, or 0.6 μm, and the like, so that the electrical performance can be ensured while the cost and process difficulty can be reduced.

For the above-described first to fourth embodiments, the thickness of the light-filtering layer CF, i.e., the thickness of the light-filtering part CFP, is not less than 1.0 μm and not more than 6.0 μm, such as 1.0 μm, 2.0 μm, 3.0 μm, 4.0 μm, 5.0 μm, or 6.0 μm.

For the first and second embodiments, the thickness of the light-absorbing layer BM is not less than 0.5 μm and not more than 2.0 μm, such as 0.5 μm, 0.7 μm, 1.0 μm, 1.2 μm, 1.5 μm, 1.7 μm or 2.0 μm.

For the above-described first to fourth embodiments, the thickness of the light-condensing layer LE is not less than 0.5 μm and not more than 5.0 μm, such as 0.5 μm, 2.0 μm, 3.0 μm, 4.0 μm, or 5.0 μm.

For the isolation layer SEP of the first and second embodiments, the critical dimension (CD) of the contact hole exposing the connection unit BLU is 2.0 μm-8.0 μm, such as 2.0 μm, 4.0 μm, 6.0 μm, or 8.0 μm.

After experimental verification, the display panel of the presently disclosed embodiment can significantly improve color shift and reduce brightness decay, as shown in the following table:

| | | Related art | Present disclosure |
|---|---|---|---|
| L-decay@30° (Brightness | | 46~50% | 42~47% |
| decay when emitting angle | | | |
| is within the range of 30°) | | | |
| Color shift | 30° | 3.8 | 4.0 |
| | 45° | 5.6 | 4.6 |
| | 60° | 5.0 | 1.8 |

An Embodiment of the present disclosure also provides a method of manufacturing a display panel, the structure of which may be referred to the embodiments of the display panel above and will not be described in detail herein. The manufacturing method of the present disclosure may include:
step S110, forming a driving backplane;
step S120, forming a light-emitting layer OL including a plurality of light-emitting elements on a side of the driving backplane;
step S130, forming a light-condensing layer having a plurality of micro-lenses on a side of the light-emitting layer OL away from the driving backplane, one of the light-emitting elements being provided to correspond to at least one of the micro-lenses in a direction perpendicular to the driving backplane, and the micro-lens being configured to converge at least a portion of light emitted by a corresponding light-emitting element; and
step S140, forming a light-filtering layer covering the light-condensing layer, the light-filtering layer including a plurality of light-filtering parts, one of the light-filtering parts being provided to correspond to one of the light-emitting elements in the direction perpendicular to the driving backplane, and a refractive index the light-filtering layer being greater than a refractive index of the light-condensing layer.

Since the details of the structures involved in the steps of the above manufacturing method have been described in detail in the embodiments of the display panel above, the details and beneficial effects thereof will not be described in detail herein.

It is to be noted that although the various steps of the manufacturing method in the present disclosure are described in the accompanying drawings in a particular order, it is not required or implied that the steps must be performed in that particular order or that all of the steps shown must be performed in order to achieve the desired results. Additionally or alternatively, certain steps may be omitted, a plurality of steps may be combined into a single step to be performed, and/or a single step may be divided into a plurality of steps to be performed.

An embodiment of the present disclosure also provides a display device that may include the display panel in any of the above embodiments. The specific structure and beneficial effects of the display panel have been described in detail in the above embodiments of the display panel, and will not be described in detail herein. The display device of the present disclosure can be used in electronic devices with image display functions such as mobile phones, tablet PCs, TVs, and the like, and will not be listed one by one herein.

Those skilled in the art may easily conceive of other embodiments of the present disclosure after considering the specification and practicing what is disclosed herein. The present application is intended to cover any variations, uses or adaptations of the present disclosure that follow the general principle of the present disclosure and include the common knowledge and the conventional technical means in the art that are not disclosed herein. The description and embodiments are considered to be exemplary only and the true scope and spirit of the present disclosure is indicated by the claims.

1. A display panel, comprising:
a driving backplane;
a light-emitting layer, provided on a side of the driving backplane and comprising a plurality of light-emitting elements;
a light-condensing layer, provided on a side of the light-emitting layer away from the driving backplane and having a plurality of micro-lenses, one of the light-emitting elements being provided to correspond to at least one of the micro-lenses in a direction perpendicular to the driving backplane; and
a light-filtering layer, covering the light-condensing layer and comprising a plurality of light-filtering parts, one of the light-filtering parts being provided to correspond to one of the light-emitting elements in the direction perpendicular to the driving backplane, and the light-filtering part covering at least one of the micro-lenses,
wherein a refractive index of each of the light-filtering parts is greater than a refractive index of the light-condensing layer, and the micro-lens is configured to converge at least a portion of light emitted by a corresponding light-emitting element.

2. The display panel according to claim 1, further comprising:
a touch layer, provided on the side of the light-emitting layer away from the driving backplane; and
a light-absorbing layer, provided on a surface of the touch layer away from the driving backplane,
wherein the light-converging layer covers the light-absorbing layer and the touch layer, and an orthographic projection of the light-absorbing layer on the driving backplane separates orthographic projections of the light-filtering parts on the driving backplane.

3. The display panel according to claim 2, wherein the touch layer comprises:
a connection layer, comprising a plurality of connection units;
an isolation layer, covering the connection layer; and
an electrode layer, provided on a surface of the isolation layer away from the driving backplane, and comprising a plurality of first touch electrodes extending in a row direction and spaced apart in a column direction, and a plurality of electrode unit groups extending in the column direction and distributed in the row direction,
wherein each of the electrode unit groups comprises a plurality of electrode units distributed in the column direction, two adjacent electrode units in the same electrode unit group are connected by one of the connection units, and the same electrode unit group and the connection units connected to the same electrode unit group form a second touch electrode, and
wherein the light-absorbing layer covers at least a portion of the electrode layer.

4. The display panel according to claim 1, further comprising:
a connection layer, comprising a plurality of connection units, the light-condensing layer covering the connection layer;
an electrode layer, provided on a surface of the light-condensing layer away from the driving backplane, and comprising a plurality of first touch electrodes extending in a row direction and spaced apart in a column direction, and a plurality of electrode unit groups extending in the column direction and distributed in the row direction, wherein each of the electrode unit groups comprises a plurality of electrode units distributed in the column direction, two adjacent electrode units in the same electrode unit group are connected by one of the connection units, and the same electrode unit group and the connection units connected to the same electrode unit group form a second touch electrode; and
a light-absorbing layer, covering at least a portion of the electrode layer and separating the light-filtering parts.

5. The display panel according to claim 1, further comprising:
a connection layer, comprising a plurality of connection units;
an isolation layer, covering the connection layer; and
an electrode layer, provided on a surface of the isolation layer away from the driving backplane, and comprising a plurality of first touch electrodes extending in a row direction and spaced apart in a column direction, and a plurality of electrode unit groups extending in the column direction and distributed in the row direction,
wherein each of the electrode unit groups comprises a plurality of electrode units distributed in the column direction, two adjacent electrode units in the same electrode unit group are connected by one of the connection units, and the same electrode unit group and the connection units connected to the same electrode unit group form a second touch electrode, and
wherein the light-condensing layer covers the electrode layer, an orthographic projection of the electrode layer on the driving backplane separates orthographic projections of the light-filtering parts on the driving backplane, and the electrode layer is a light-absorbing conductive structure.

6. The display panel according to claim 1, further comprising:
a connection layer, comprising a plurality of connection units, the light-condensing layer covering the connection layer; and
an electrode layer, provided on a surface of the light-condensing layer away from the driving backplane, and comprising a plurality of first touch electrodes extending in a row direction and spaced apart in a column direction, and a plurality of electrode unit groups extending in the column direction and distributed in the row direction,
wherein each of the electrode unit groups comprises a plurality of electrode units distributed in the column direction, two adjacent electrode units in the same electrode unit group are connected by one of the connection units, and the same electrode unit group and the connection units connected to the same electrode unit group form a second touch electrode, and
wherein the electrode layer separates the light-filtering parts, and the electrode layer is a light-absorbing conductive structure.

7. The display panel according to claim 5, wherein the electrode layer is a mesh structure having a plurality of mesh holes, each of the mesh holes is surrounded by a plurality of electrode wires, and adjacent mesh holes share at least one of the electrode wires, and
one of the light-filtering parts is provided to correspond to one of the mesh holes in the direction perpendicular to the driving backplane, and a width of the electrode wire is not less than a distance between two adjacent light-filtering parts.

8. The display panel according to claim 5, wherein the electrode layer comprises a first conductive layer, a second conductive layer and a light-absorbing material layer, and
wherein the second conductive layer covers a surface of the first conductive layer away from the driving backplane, and at least a portion of the light-absorbing material layer covers a surface of the second conductive layer away from the driving backplane.

9. The display panel according to claim 8, wherein the light-absorbing material layer covers sidewalls of the first conductive layer and the second conductive layer.

10. The display panel according to claim 8, wherein a material of at least one of the light-absorbing material layer and the first conductive layer is a light-absorbing conductive material.

11.-12. (canceled)

13. The display panel according to claim 1, wherein the light-filtering part comprises a base material and scattering particles dispersed in the base material.

14. (canceled)

15. The display panel according to claim 1, wherein the light-emitting layer comprises a plurality of light-emitting units distributed in an array, each of the light-emitting units comprises at least two light-emitting elements having different light-emitting colors, and a color of any one of the filtering parts is the same as the light-emitting color of a corresponding light-emitting element.

16. The display panel according to claim 1, wherein the light-condensing layer has a plurality of the micro-lenses within a range of the light-condensing layer covered by one of the light-filtering parts.

17. The display panel according to claim 3, further comprising:
an encapsulation layer, covering the light-emitting layer,
wherein the connection layer is provided on a side of the encapsulation layer away from the driving backplane.

18. The display panel according to claim 8, wherein the electrode layer has a thickness of not less than 0.1 μm and not greater than 0.6 μm.

19. The display panel according to claim 1, wherein the light-filtering layer has a thickness of not less than 1.0 μm and not greater than 6.0 μm.

20. The display panel according to claim 2, wherein the light-absorbing layer has a thickness of not less than 0.5 μm and not greater than 2.0 μm.

21. The display panel according to claim 1, wherein the light-condensing layer has a thickness of not less than 0.5 μm and not greater than 5.0 μm.

22. A method of manufacturing a display panel, comprising:
forming a driving backplane;
forming a light-emitting layer comprising a plurality of light-emitting elements on a side of the driving backplane;
forming a light-condensing layer having a plurality of micro-lenses on a side of the light-emitting layer away from the driving backplane, one of the light-emitting elements being provided to correspond to at least one of the micro-lenses in a direction perpendicular to the driving backplane, and the micro-lens being configured to converge at least a portion of light emitted by a corresponding light-emitting element; and
forming a light-filtering layer covering the light-condensing layer, the light-filtering layer comprising a plurality of light-filtering parts, one of the light-filtering parts being provided to correspond to one of the light-emitting elements in the direction perpendicular to the driving backplane, and a refractive index the light-filtering layer being greater than a refractive index of the light-condensing layer.

23. (canceled)

24. The display panel according to claim 7, wherein the electrode layer is a mesh structure having a plurality of mesh holes, each of the mesh holes is surrounded by a plurality of electrode wires, and adjacent mesh holes share at least one of the electrode wires, and
one of the light-filtering parts is provided to correspond to one of the mesh holes in the direction perpendicular to the driving backplane, and a width of the electrode wire is not less than a distance between two adjacent light-filtering parts.
